(19) United States
(12) Patent Application Publication
(10) Pub. No.: US 2016/0056065 A1
(43) Pub. Date: Feb. 25, 2016

(54) METHOD AND APPARATUS FOR REMOVING EXPERIMENTAL ARTIFACTS FROM ENSEMBLE IMAGES

(71) Applicant: Robert E. Stahlbush, Silver Spring, MD (US)

(72) Inventor: ROBERT E. STAHLBUSH, Silver Spring, MD (US)

(21) Appl. No.: 14/826,270

(22) Filed: Aug. 14, 2015

Related U.S. Application Data
(60) Provisional application No. 62/041,630, filed on Aug. 25, 2014.

(51) Int. Cl. H01L 21/67; H01L 21/66

(52) U.S. Cl. CPC H01L 21/67288; H01L 22/12

(57) ABSTRACT

A method and apparatus wherein a photoluminescence in a semiconductor wafer is excited using an ultraviolet light source. A plurality of partial raw images of the photoluminescence is generated. The plurality of partial raw images includes at least one equipment-generated artifact The at least one equipment-generated artifact is removed from the cluster of partial raw images using the equipment-generated artifact image to generate a cluster of partial processed images. A plurality of clusters of partial processed images is generated. The plurality of clusters of partial processed images are aligned and combined to generate a wafer image tree of the at least one equipment-generated artifact.

### CROSS-REFERENCE TO RELATED APPLICATIONS

This application claims priority to U.S. Provisional Patent Application Ser. No. 62/041,630, entitled “METHOD OF REMOVING EXPERIMENTAL ARTIFACTS FROM ENSEMBLE MAGES COLLECTED USING STEP-AND-REPEAT IMAGING OPERATIONS,” to Stahlbush, which was filed on 25 Aug. 2014 and is incorporated herein by reference.

### FIELD OF THE INVENTION

The present invention relates to semiconductor wafer fabrication. More particularly, the present invention involves improvements in the techniques of imaging defects over wafer-scale areas.

### BACKGROUND OF THE INVENTION

Current techniques of imaging defects over wafer-scale areas includes spot scanning techniques, where an ultraviolet beam is focused to a small spot (i.e., about a micron) and scanned over the area to be imaged as the photoluminescence from that spot is recorded. This technique has difficulties with carrier diffusion from the ultraviolet spot that results in poor resolution (i.e., on the order tens of microns). The local intensity near the spot is also too high to be able to image many of the dislocations of interest due to the decrease in imaging contrast at high local illumination intensity.

It is theoretically possible to directly eliminate the experimental artifacts, by using a smaller, more uniform part of the illuminating ultraviolet laser beam, where the artifacts due to this illumination could be reduced. However, the trade-off is that either a more powerful and much more expensive laser would be required and/or longer partial image collection times (e.g., tens of hours versus just hours) would be required. There are also limits to the perfection of the charge-coupled-devices that collect the images. Moreover, the whole setup would have to be run in a dust-free environment.

Previous attempts involving an alternate technique of step-and-repeat imaging have not proved successful. With this alternate attempt at using the step-and-repeat imaging technique, a larger area is illuminated by ultraviolet light and an. image of this area Is optically magnified (about a millimeter square) and collected with a charge-coupled-device or other similar imaging device. In this alternate technique, because the illuminated area is orders of magnitude larger than the spot scanning technique, it does not have carrier diffusion problems and the low local intensity provides clear images of most but not all dislocations of interest. However, the disadvantage of the alternate step-and-repeat image processing is that, it is difficult to sufficiently suppress the experimental artifacts caused by the imaging experimental hardware setup. These hardware introduced artifacts produce intensity variations that often obscure subtle intensity variation from the sample. Neither, the spot scanning method nor the alternate step-and-repeat imaging technique provides a full-wafer, wide dynamic range of sample features including low contrast features, of high resolution images.

### BRIEF SUMMARY OF THE INVENTION

Applicant recognized a need for a method and apparatus to create full-wafer, high resolution images to see dislocations and other extended defects in the growth of semiconductor epitaxy. Further, Applicant recognized a need for an imaging technique that separates the intensity variations caused by the experimental setup from the intensity variations associated with the wafer-sample. Additionally, Applicant recognized a need for a method of suppressing the experimental setup artifacts and providing resolution more than an order of magnitude higher than obtained by scanning a focused spot of the wafer-sample.

An embodiment of the invention removes experimental artifacts from images assembled from an ensemble of images collected by a standard step-and-repeat process. In an illustrative step-and-repeat process, each partial image is a small part of the final full image, and the final full image is constructed from a sequence of partial images collected one at a time. The embodiment of the invention includes a numerical method to generate the final full image that suppresses the intensity variations due to the imaging apparatus, and enables observation of subtle, low contrast, features of the wafer sample.

An embodiment of the invention makes it possible to observe a wider than previously possible dynamic range of sample features including low contrast features from the semiconductor wafer sample being imaged. The artifacts are intensity variations due to equipment limitations that introduce apparent, though not real, structure into the partial images. The equipment limitations include, for example, non-uniform illumination of the partial images, non-uniform response of the imaging device and non-uniform transmission of optical elements.

### BRIEF DESCRIPTION OF THE DRAWINGS

FIG. 1 illustrates an illustrative system according to an embodiment of the instant invention.

FIG. 2A is an illustrative graphic showing fifteen partial images of part of a whole-wafer ultraviolet photoluminescence (“UVPL”) image, before numerical image processing according to an embodiment of the instant invention.

FIG. 2B illustrates a. graphic showing part of a whole-wafer UVPL image, after numerical image processing according to an embodiment of the instant invention.

### DETAILED DESCRIPTION OF THE INVENTION

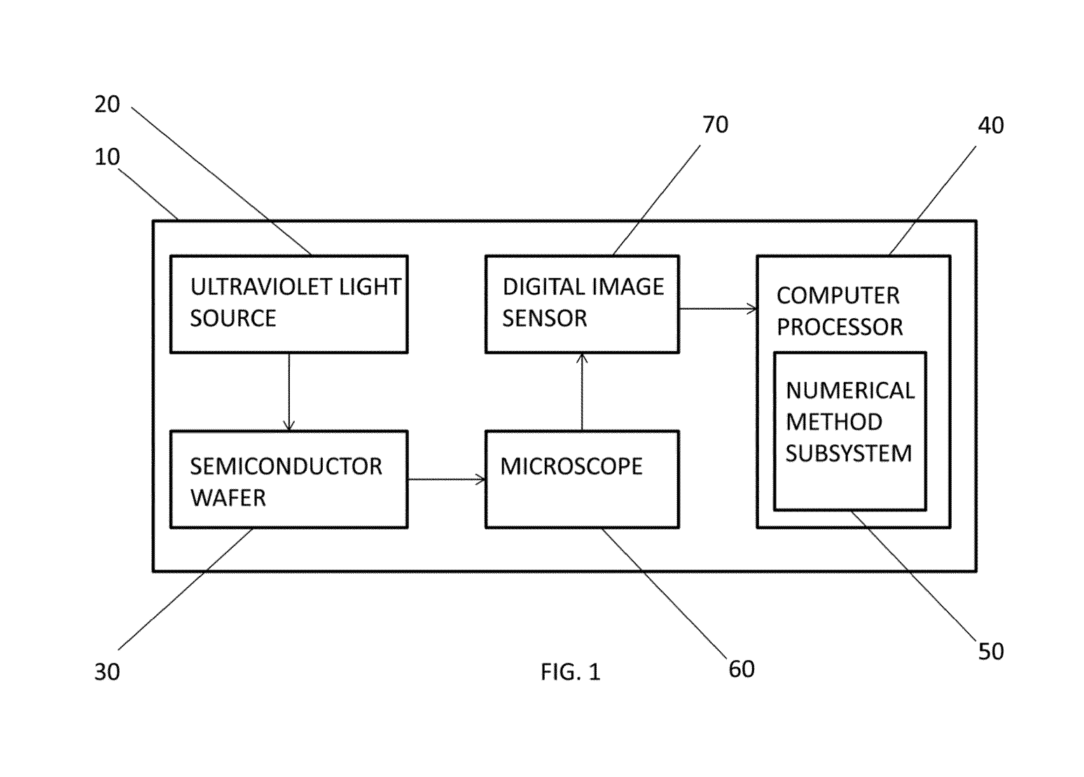

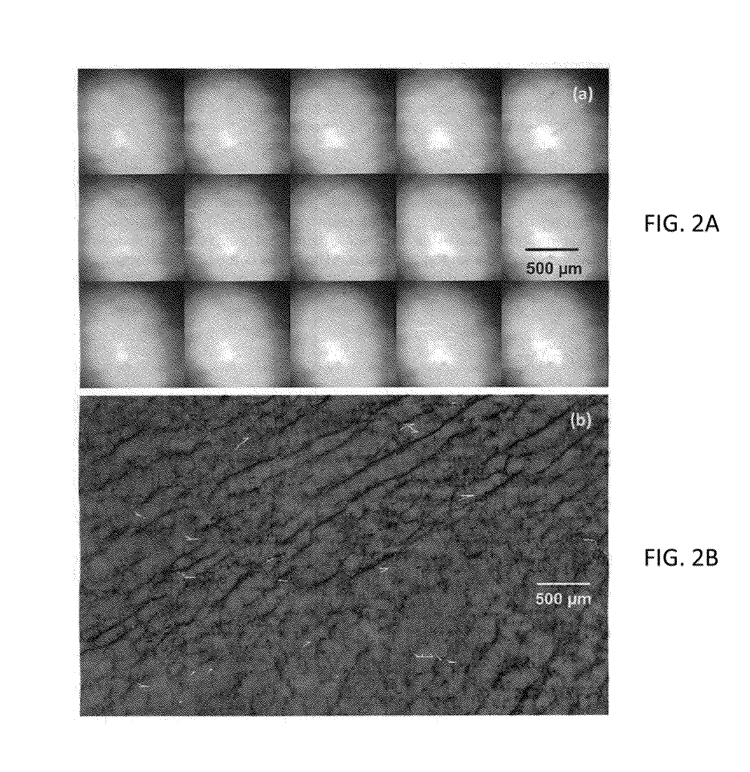

An embodiment of the invention, includes a method, which, is described below with reference by way of illustration to FIGS. 1, 2A and 2B. A photoluminescence in a semiconductor wafer 30 is excited using an ultraviolet light source. A plurality of partial raw images of the photoluminescence is generated, as shown by way of illustration in FIG. 2A. The plurality of partial raw images includes at least one equipment-generated artifact. A cluster of partial raw images is selected from the plurality of partial raw images. An equipment-generated artifact image comprising the at least one equipment-generated artifact is generated by numerically comparing the partial raw images of the cluster. The at least one equipment-generated artifact, is removed from the cluster of partial, raw images using the equipment-generated artifact image to generate a cluster of partial processed images. The selecting a cluster of partial raw images from the plurality of partial raw images, the generating an equipment-generated artifact image comprising at least one equipment-generated artifact by numerically comparing the partial raw images of the cluster, and the removing the at least one equipment-generated artifact from the cluster of partial raw images using the equipment-generated artifact image are repeated to generate a plurality of clusters of partial processed images. The plurality of clusters of partial processed images are aligned and combined to generate a final wafer image free of the at least one equipment-generated artifact, as shown by way of illustration in FIG. 2B.

Optionally, the wafer includes at least one standard epitaxial layer on a standard substrate, the at least one epitaxial layer including a standard direct bandgap semiconductor or a standard indirect band semiconductor. Optionally, the direct bandgap semiconductor includes gallium nitride GaN, aluminum, nitride AlN, or gallium oxide Ga₂O₃ and the indirect bandgap semiconductor includes silicon carbide SiC, silicon Si, germanium Ge, or diamond.

Optionally, the ultraviolet light source comprises a standard coherent ultraviolet light source or a standard incoherent ultraviolet light source. Optionally, the coherent ultraviolet light source includes a standard argon ion laser, a standard frequency-tripled yttrium aluminum garnet laser (such as a standard frequency-tripled Nd:YAG 355 nm laser), a standard He—Cd 325 nm laser, a standard Kr—Ag 224 nm laser, a standard nitrogen 33 nm laser, a standard ArF 193 nm excimer laser, a standard KrF 248 nm excimer, a standard XeCl 308 nm excimer laser, or a standard XeF 351 nm excimer laser, and optionally, the incoherent ultraviolet light source includes a standard mercury argon are lamp or a standard ultraviolet light-emitting diode.

Optionally, this method embodiment further includes the following. The photoluminescence is collected using a standard microscope sensitive to a visible to near-infrared wavelength spectrum. The photoluminescence is imaged using a standard digital image sensor to generate a full raw wafer image from which to generate the plurality of partial raw images. Optionally, the generating a plurality of partial raw images of the photoluminescence includes: performing a stepping and repeating process on the full raw wafer image to generate the plurality of partial raw images of the photoluminescence. Optionally, the digital image sensor includes a quantum efficiency greater than 70%, a dark current noise less than 1/10 per second, and/or a readout noise less than 5 counts per reading. Optionally, the digital, image sensor includes a charge-coupled device or a complementary metal-oxide semiconductor active-pixel sensor.

Optionally, the plurality of partial raw images includes at least 20 partial raw images.

Another embodiment of the invention includes an apparatus 10, which is described below with reference by way of illustration to FIG. 1. The apparatus 10 includes a standard ultraviolet light source 20 configured to excite a photoluminescence in a standard semiconductor wafer 30, and a standard computer processor 40. The computer processor 40 includes a numerical method subsystem 50 that performs the following steps. A plurality of partial raw images of the photoluminescence is generated. The plurality of partial raw images includes at least one equipment-generated artifact. A cluster of partial raw images is selected from the plurality of partial raw images. An equipment-generated artifact image comprising the at least one equipment-generated artifact is generated, by numerically comparing the partial raw images of the cluster. The at least one equipment-generated artifact is removed from the cluster of partial raw images using the equipment-generated artifact image to generate a cluster of partial processed images. The selecting a cluster of partial raw images from the plurality of partial raw images, the generating an equipment-generated artifact image comprising at least one equipment-generated artifact by numerically comparing the partial raw images of the cluster, and the removing the at least one equipment-generated artifact from the cluster of partial raw images using the equipment-generated artifact image are repeated to generate a plurality of clusters of partial processed images. The plurality of clusters of partial processed images are aligned and combined to generate a wafer image free of the at least one equipment-generated artifact.

Optionally, the apparatus further includes a standard microscope 60 sensitive to a visible to near-infrared wavelength spectrum and configured to collect the photoluminescence; and the apparatus further includes a standard digital image sensor 70 configured to image the photoluminescence to generate a full raw wafer image from which to generate the plurality of partial raw images. Optionally, the digital image sensor 70 includes a quantum efficiency greater than 70%, a dark current noise less than 1/10 per second, and/or a readout noise less than 5 counts per reading. Optionally, the digital image sensor 70 comprises a standard charge-coupled device or a standard complementary metal-oxide semiconductor active-pixel sensor.

Optionally, the ultraviolet light source 20 includes a standard coherent ultraviolet-light source or a standard incoherent ultraviolet light source. Optionally, the coherent ultraviolet light source includes a standard argon ion laser, a standard frequency-tripled yttrium aluminum garnet laser (such as a standard frequency-tripled Nd:YAG 355 nm laser), a standard He—Cd 325 nm laser, a standard Kr—Ag 224 nm laser, a standard, nitrogen 337 nm laser, a standard ArF 193 nm excimer laser, a standard KrF 248 nm excimer, a standard XeCl 308 nm excimer laser, or a standard XeF 351 nm excimer laser, and wherein the incoherent ultraviolet light source includes a standard mercury argon arc lamp or a standard ultraviolet light-emitting diode.

Another embodiment of the invention includes a method having the following steps (S100-S700). In Step S100, a collection of raw images covering a photoluminescent area of interest of a semiconductor wafer 30 is collected by a standard step-and-repeat process. Each raw image includes pixels. For example, each pixel includes a grayscale value. As another example, each pixel include color value, wherein either every color value is converted to a grayscale equivalent, or every color value is broken down into its red, green, and blue component values. In Step S200, for each, raw image, the median (grayscale or color) intensity value of the pixels within the each raw image is determined. In an illustrative embodiment of Step S200, a wide dynamic range of pixel intensity variations is beneficial, for example, each pixel has a 16-bit value range representing its grayscale or color.

In Step S300, based on the image median values and order of collection, the images

are divided into contiguous clusters. In an illustrative embodiment of Step S300, when forming clusters, the range of raw image median values and the range of image collection times should be kept as small as possible relative to the number of images in the cluster. Each cluster must be large enough to do the averaging discussed below and still be structurally meaningful. At the same time, each cluster must be sufficiently compact to keep experimental artifacts constant within the cluster. For example, 40 to 60 are an illustrative number of clusters for a 100 mm diameter wafer for which 8000 raw images are collected.

In Step S400 of this embodiment of the invention, an experimental artifact image is generated for each cluster. In an illustrative embodiment of Step S400, a three-dimensional array of pixels is generated, wherein the -first and second dimensions represent the raw image size; the third dimension represents the respective number of the raw image, wherein the respective number is in the range from 1 to the number of images in the cluster. The three-dimensional array is sorted along the third dimension according to pixel intensity for given x and y pixel coordinates. Along the third dimension, low and high index parts of the three-dimensional array are discarded because such parts are likely due to strong features of the image that should be preserved and are not experimental artifacts. For example, the low and high index parts are the lowest 25% and the highest 25%. Along the third dimension, the average of the remaining pixels in the three-dimensional array is taken. It has been determined empirically that, with well-chosen clusters, this average is a close approximation of the experimental artifact image. The three-dimensional array generating, three-dimensional array sorting, and remaining pixels-averaging steps are repeated for each cluster.

In Step S500, intermediate images using the raw images and experimental artifact images are generated. In an illustrative embodiment of Step S500, for each raw image the corresponding experimental artifact image is used for the same location. A normalized experimental artifact (“NEA”) image is generated, wherein the median pixel intensity equals one. The intermediate images are generated by dividing the raw images by the NBA image.

In Step S600, final images are generated from the intermediate images. In an illustrative embodiment of Step S600, for each intermediate image, a low pass image version thereof (“ImLP1”) is generated by convoluting it with a normalized Gaussian. A typical sigma equals 50 pixels. For each pixel in an intermediate image, a range is defined, as equal to const*sqrt(ImLP1), where a typical constant=10 and sqrt is the square root of each pixel in the low pass image. The pixels in each intermediate image are divided into two sets. For each pixel where the difference between the intermediate image and ImLP1 is more than the above defined range, the pixels value is set to the ImLP1 value, and all other pixels are set to the pixel value in the intermediate image. Together, modified images are generated. A second low pass image version (“ImLP2”) is generated by convoluting each modified image with the same normalized Gaussian as above. Final partial images are generated by subtracting ImLP2 from each intermediate image.

In Step S700, a final complete image of the wafer is generated by placing the final partial images together, each in its proper position.

Referring by way of illustration to FIGS. 2A and 2B, whole-wafer ultraviolet photoluminescence imaging of dislocations and other extended defects in a semiconductor epitaxial layer involves a standard step-and-repeat collection of partial images followed by numerically assembling the full image from the partial images. The photoluminescence is excited by ultraviolet light from an argon ion laser 204. The luminescence is collected by a microscope 208 and imaged by a charge-coupled-device 206. Depending on the extended defects to be imaged, an appropriate filter is chosen to maximize the contrast of the defects to be imaged.

A feature to note in the final mil image assembly process is the ability to separate intensity variations in the photoluminescence due to the semiconductor epitaxial layer defects from intensity variations that are artifacts of the equipment, such as an argon ion laser, a microscope, and/or a charge-coupled-device. The contrast caused by the many extended defects is weak; furthermore, without suppressing the image variations caused by the experimental hardware artifacts, many details of the extended defects are obscured in the final full image.

The partitioning of intensity variations between experimental hardware induced artifacts and intensity variations caused by the defects in the wafer-sample is accomplished by numerically comparing all of the partial images to distinguish image variations that are in common from image variations that are not in common. The essential idea is that the intensity variations m common are due to imperfections in the experimental hardware devices, while intensity variations not in common are caused by wafer-sample defects. The numerical method according to an embodiment of the instant invention separates the two types of intensity variations and creates the final full image with the experimental artifacts suppressed. Part of a whole-wafer ultra violet photoluminescence image from a typical wafer-sample is shown in FIG. 2A, where fifteen of the partial images are shown before numerical processing. FIG. 2B shows part of a whole-wafer UVPL image, after numerical image processing has been performed, where the artifacts have been suppressed by the numerical method according to an embodiment of the instant invention. The most obvious difference between the illustrated images is that there is intensity falloff near the comers of each of the fifteen partial image views due to the non-uniform laser illumination. There are also a number of more subtle features that can be seen in each of the fifteen partial images. All features that are in common in the fifteen raw images are suppressed, as illustrated in FIG. 2B, which shows the numerically processed image. The result is that wafer-sample details in the areas that had artifacts are no longer obscured.

Another embodiment of the invention includes a method having the following illustrative steps. Partial images are collected one at a time in a standard step-and-repeat process. The size of each partial image is on the order of 1 mm² and the resolution of each image is on the order of a micron. Coverage of the whole area of, for example, a 4-inch diameter SiC wafer-sample involves, in an illustrative embodiment, the collection of about 8000 partial images. This collection is accomplished by having the wafer-sample mounted under the imaging apparatus (such as a charge-coupled-device) on a precision stage. The intensity variations m each of the partial images are a combination of variations due to the epitaxial layer on the wafer-sample and of variations from numerous imperfections in the imaging apparatus (i.e., artifacts of the apparatus). A distinction between the two sources of intensity variations is that the variations introduced by the experimental apparatus are nearly the same for two subsequent partial images and vary only slightly over a large number of partial images. The numerical method subsystem according to an embodiment of the instant invention creates images that are due to the imaging apparatus. This involves averaging a large number of the partial images while preventing any strong intensity variations due to the wafer from affecting the averaging process. An intermediate set of partial images is created that covers the whole area in the final lull image and that is nearly completely due to intensity variations from the imaging apparatus. This set of images is used to remove the experimental artifacts from the original set of partial images and to create a set of partial images almost completely due to variations from the epitaxial layer on the wafer. This final set of images is combined to form the final UVPL image. Its black and white levels are adjusted to from the clearest image.

In this embodiment of the invention, during the collection operation of the step-and-repeat imaging over the whole area of the sample to imaged, many of the important features are low contrast and easily obscured by intensity variations introduced by the imaging apparatus. These experiment-hardware-induced artifacts in the individual images are due to equipment limitations that introduce apparent structure that obscures imaging details from the wafer-sample. The variations include non-uniform illumination of the partial images, non-uniform response of the charge-coupled-device or other imaging device, and non-uniform transmission of the optical elements.

Portions of the invention operate in a standard computing operating environment, for example, a desktop computer, a laptop computer, a mobile computer, a server computer, and the like, in which embodiments of the invention may be practiced. While the invention is described in the general context of program modules that run on an operating system on a personal computer, those skilled in the art will recognize that the invention may also be implemented in combination with other types of computer systems and program modules.

Generally, program modules include routines, programs, components, data structures, and other types of structures that perform particular tasks or implement particular abstract data types. Moreover, those skilled in the art will appreciate that the invention may be practiced with other computer system configurations, including hand-held devices, multiprocessor systems, microprocessor-based or programmable consumer electronics, minicomputers, mainframe computers, autonomous embedded computers, and the like. The invention may also be practiced in distributed computing environments where tasks are performed by remote processing devices that are linked through a communications network. In a distributed computing environment, program modules may be located in both local and remote memory storage devices.

An illustrative operating environment for embodiments of the invention will be described. A computer comprises a general purpose desktop, laptop, handheld, mobile or other type of computer (computing device) capable of executing one or more application programs. The computer includes at least one central processing unit (“CPU”), a system memory, including a random access memory (“RAM”) and a read-only memory (“ROM”), and a system bus that couples the memory to the CPU. A basic input/output system containing the basic routines that help to transfer information between elements within the computer, such as during startup, is stored in the ROM. The computer further includes a mass storage device for storing an operating system, application programs, and other program modules.

The mass storage device is connected to the CPU through a mass storage controller (not shown) connected to the bus. The mass storage device and its associated computer-readable media provide non-volatile storage for the computer. Although the description of computer-readable media contained herein refers to a mass storage device, such as a hard disk or CD-ROM drive, it should be appreciated by those skilled in the art that computer-readable media can be any available media that can be accessed or utilized by the computer.

By way of example, and not limitation, computer-readable media may comprise computer storage media and communication media. Computer storage media includes volatile and non-volatile, removable and non-removable media implemented in any method or technology for storage of information such as computer -readable instructions, data structures, program modules or other data. Computer storage media includes, but is not limited to, RAM, ROM, EPROM, EEPROM, flash memory or other solid state memory technology, CD-ROM, digital versatile disks (“DVD”), or other optical storage, magnetic cassettes, magnetic tape, magnetic disk storage or other magnetic storage devices, or any other tangible non-transitory medium which can be used to store the desired information and which can be accessed by the computer.

According to various embodiments of the Invention, the computer may operate in a networked environment using logical connections to remote computers through a network, such as a local network, the Internet, etc. for example. The computer may connect to the network through a network interface unit connected to the bus. It should be appreciated that the network interface unit may also he utilized to connect to other types of networks and remote computing systems.

The computer may also include an input/output controller for receiving and processing input from a number of other devices, including a keyboard, mouse, etc. Similarly, an input/output controller may provide output to a display screen, a printer, or other type of output device.

As mentioned briefly above, a number of program modules and data files may be stored in the mass storage device and RAM of the computer, including an operating system suitable for controlling the operation of a networked personal computer. The mass storage device and RAM may also store one or more program modules. In particular, the mass storage device and the RAM may store application programs, such as a software application, for example, a word processing application, a spreadsheet application, a slide presentation application, a database application, etc.

It should be appreciated that various embodiments of the present invention may be implemented as a sequence of computer-implemented, acts or program modules running on a computing system and/or as interconnected machine logic circuits or circuit modules within the computing system. The implementation is a matter of choice dependent on the performance requirements of the computing system implementing the invention. Accordingly, logical operations including related, algorithms can be referred to variously as operations, structural devices, acts or modules. It will be recognized by one skilled in the art that these operations, structural devices, acts and modules may be implemented in software, firmware, special purpose digital logic, and any combination thereof without deviating from the spirit and scope of the present invention as described herein.

Although a particular feature of the disclosure may have been illustrated and/or described with respect to only one of several implementations, such feature may be combined with one or more other features of the other implementations as may be desired and advantageous for any given or particular application. Also, to the extent that the terms “including”, “includes”, “having”, “has”, “with”, or variants thereof are used in the detailed description and/or in the claims, such terms are intended to be inclusive in a manner similar to the term “comprising”.

This written description sets forth the best mode of the invention and provides examples to describe the invention and to enable a person of ordinary skill in the art to make and use the invention. This written description does not limit the invention to the precise terms set forth. Thus, while the invention has been described in detail with reference to the examples set forth above, those of ordinary skill in the art may effect alterations, modifications and variations to the examples without departing from the scope of the invention.

These and other implementations are within the scope of the following claims.

What is claimed as new and desired to be protected by Letters Patent of the United States is:

1. A method comprising:
exciting a photoluminescence in a wafer using an ultraviolet light source;
generating a plurality of partial raw images of the photoluminescence, the plurality of partial raw images comprising at least one equipment-generated artifact;
selecting a cluster of partial raw images from the plurality of partial raw images;
generating an equipment-generated artifact image comprising the at least one equipment-generated artifact by numerically comparing the partial raw images of the cluster;
removing the at least one equipment-generated artifact from the cluster of partial raw images using the equipment-generated artifact image to generate a cluster of partial processed images;
repeating said selecting a cluster of partial raw images from the plurality of partial raw images, said generating an equipment-generated artifact image comprising at least one equipment-generated artifact by numerically comparing the partial raw images of the cluster, and said removing the at least one equipment-generated artifact from the cluster of partial raw images using the equipment-generated artifact image to generate a plurality of clusters of partial processed images
aligning and combining the plurality of clusters of partial processed images to generate a wafer image free of the at least one equipment-generated artifact.

2. The method according to claim 1, wherein the wafer comprises at least one epitaxial layer on a substrate, the at least one epitaxial layer comprising one of a direct bandgap semiconductor and an indirect band semiconductor.

3. The method according to claim 2, wherein the direct bandgap semiconductor comprises one of gallium nitride GaN, aluminum nitride AlN, gallium oxide Ga₂O₃ and the indirect bandgap semiconductor comprises one of silicon, carbide SiC, silicon Si, germanium Ge, and diamond.

4. The method according to claim 1, wherein the ultraviolet light source comprises one of a coherent ultraviolet light source and an incoherent ultraviolet light source.

5. The method according to claim 4, wherein the coherent ultraviolet light source comprises one of an argon ion laser, a frequency-tripled yttrium aluminum garnet laser, a frequency-tripled Nd:YAG laser, a He—Cd laser, a Kr—Ag laser, a nitrogen laser, an argon, fluoride ArF excimer laser, a xenon, chloride XeCl excimer laser, and a xenon fluoride XeF excimer laser, and
wherein the incoherent ultraviolet light source comprises one of a mercury argon arc lamp and an ultraviolet light-emitting diode.

6. The method according to claim 1, further comprising:
collecting the photoluminescence using a microscope sensitive to a visible to near-infrared wavelength spectrum; and
imaging the photoluminescence using a digital image sensor to generate a full raw wafer image from which to generate the plurality of partial raw images.

7. The method according to claim 6, wherein said generating a plurality of partial raw images of the photoluminescence comprises:
performing a stepping and repeating process on the full raw wafer image to generate the plurality of partial raw images of the photoluminescence.

8. The method according to claim 6, wherein the digital image sensor comprises at least one of a quantum efficiency greater than 70%, a dark, current noise less than 1/10 per second, and a -readout noise less than 5 counts per reading.

9. The method, according to claim 8, wherein, the digital image sensor comprises one of a charge-coupled device and a complementary metal-oxide semiconductor active-pixel sensor.

10. The method according to claim 1, wherein the plurality of partial raw images comprises at least 20 partial raw images.

11. An apparatus comprising:
an ultraviolet light source configured to excite a photoluminescence in a wafer;
a computer processor performing the steps of:
generating a plurality of partial raw images of the photoluminescence, the plurality of partial raw images comprising at least one equipment-generated artifact;
selecting a cluster of partial raw images from the plurality of partial raw images;
generating an equipment-generated artifact image comprising the at least one equipment-generated artifact by numerically comparing the partial raw images of the cluster;
removing the at least one equipment-generated artifact from the cluster of partial raw images using the equipment-generated artifact image to generate a cluster of partial processed images;
repeating said selecting a cluster of partial raw images from the plurality of partial raw images, said generating an equipment-generated artifact image comprising at least one equipment-generated artifact by numerically comparing the partial raw images of the cluster, and said removing the at least one equipment-generated artifact from the cluster of partial raw images using the equipment-generated artifact image to generate a plurality of clusters of partial processed images
aligning and combining the plurality of clusters of partial processed images to generate a wafer image free of the at least one equipment-generated artifact.

12. The apparatus according to claim 11, further comprising:
a microscope sensitive to a visible to near-infrared wavelength spectrum and configured to collect the photoluminescence; and
a digital image sensor configured to image the photoluminescence to generate a full raw wafer image from which to generate the plurality of partial raw images.

13. The apparatus according to claim 11, wherein the ultraviolet light source comprises one of a coherent ultraviolet light source and an incoherent ultraviolet light source.

14. The apparatus according to claim 13, wherein the coherent ultraviolet light source comprises one of an argon ion laser, a frequency-tripled yttrium aluminum garnet laser, a frequency-tripled Nd:YAG laser, a He—Cd laser, a Kr—Ag laser, a nitrogen laser, an ARF excimer laser, a XeCl excimer laser, and a XeF excimer laser, and
wherein the incoherent ultraviolet light source comprises one of a mercury argon, are lamp and an ultraviolet light-emitting diode.

15. The apparatus according to claim 12, wherein the digital image sensor comprises at least one of a quantum efficiency greater than 70%, a dark current noise less than 1/10 per second, and a readout noise less than 5 counts per reading.

17. The apparatus according to claim 15, wherein the digital image sensor comprises one of a charge-coupled device and a complementary metal-oxide semiconductor active-pixel sensor.
